(19) United States
(12) Patent Application Publication
(10) Pub. No.: US 2025/0246493 A1
(43) Pub. Date: Jul. 31, 2025

(54) SEMICONDUCTOR DEVICE

(71) Applicants: TOSHIBA ELECTRONIC DEVICES & STORAGE CORPORATION, Tokyo (JP); KABUSHIKI KAISHA TOSHIBA, Tokyo (JP)

(72) Inventor: Hisashi TOMITA, Yokohama Kanagawa (JP)

(73) Assignees: TOSHIBA ELECTRONIC DEVICES & STORAGE CORPORATION, Tokyo (JP); KABUSHIKI KAISHA TOSHIBA, Tokyo (JP)

(21) Appl. No.: 19/078,786

(22) Filed: Mar. 13, 2025

Related U.S. Application Data
(63) Continuation of application No. PCT/JP2024/007144, filed on Feb. 27, 2024.

(30) Foreign Application Priority Data
Jul. 14, 2023 (JP) 2023-115902

(51) Int. Cl. H01L 23/31; H01L 23/00; H01L 25/07

(52) U.S. Cl. CPC H01L 23/3135; H01L 24/05; H01L 24/08; H01L 24/13; H01L 24/16; H01L 25/072; H01L 2224/05647; H01L 2224/05655; H01L 2224/05657; H01L 2224/0566; H01L 2224/05664; H01L 2224/05676; H01L 2224/0568; H01L 2224/05684; H01L 2224/08221; H01L 2224/13111; H01L 2224/13116; H01L 2224/13139; H01L 2224/13144; H01L 2224/13147; H01L 2224/13155; H01L 2224/16227; H01L 2924/13055

(57) ABSTRACT

A semiconductor element extends along a first plane, includes opposing first and second surfaces and a third surface extending between respective ends of the first and second surfaces, and includes first and second electrode pads respectively provided in regions including the first and second surfaces. A first conductor is in contact with a first electrode pad and a first electrode. A second conductor is in contact with the second electrode pad and a second electrode. An insulating cover includes a first portion covering the third surface, a second portion connected to the first portion and opposing the first surface, and a third portion connected to the first portion, opposing the second surface, and sandwiching the semiconductor element with the second portion.

### CROSS-REFERENCE TO RELATED APPLICATIONS

This application is a Continuation Application of PCT Application No. PCT/JP2024/007144, filed Feb. 27, 2024 and based upon and claiming the benefit of priority from Japanese Patent Application No. 2023-115902, filed Jul. 14, 2023, the entire contents of all of which are incorporated herein by reference.

### FIELD

Embodiments described herein relate generally to a semiconductor device.

### BACKGROUND

As a power semiconductor device, an insulated gate bipolar transistor (IGBT) and an injection enhanced gate transistor (IEGT) are known. A chip of these semiconductor devices includes a collector electrode pad in one of two opposing surfaces and an emitter electrode pad in the other surface. An electrode is attached to each of the collector electrode pad and the emitter electrode pad. Since the power semiconductor device is applied with a high voltage, it is required to withstand application of the high voltage.

### BRIEF DESCRIPTION OF THE DRAWINGS

FIG. 1 shows an example of the structure of a conversion device including a semiconductor device according to a first embodiment.

FIG. 2 shows an example of a sectional structure of a semiconductor module including the semiconductor device according to the first embodiment.

FIG. 3 shows an example of a planar structure of the semiconductor device according to the first embodiment.

FIG. 4 shows an example of a planar structure of the semiconductor device according to the first embodiment.

FIGS. 5, 6, and 7 each shows an example of a sectional structure of the semiconductor device according to the first embodiment.

FIGS. 8 and 9 each shows a part of a manufacturing process of the semiconductor device according to the first embodiment.

FIG. 10 shows an example of a sectional structure of the semiconductor device according to a modification of the first embodiment.

### DETAILED DESCRIPTION

In general, according to one embodiment, a semiconductor device comprising includes a semiconductor element, a first conductor, a first electrode, a second conductor, a second electrode, and an insulating cover. The semiconductor element extends along a first plane, includes a first surface, a second surface opposing the first surface, and a third surface extending between an end of the first surface and an end of the second surface, and includes a first electrode pad provided in a region including the first surface, and a second electrode pad provided in a region including the second surface. The first conductor is in contact with the first electrode pad. The first electrode is in contact with the first conductor. The second conductor is in contact with the second electrode pad. The second electrode is in contact with the second conductor. The insulating cover includes a first portion, a second portion, and a third portion. The first portion coves the third surface. The second portion is connected to the first portion and opposing the first surface. The third portion is connected to the first portion, opposes the second surface, and sandwiches the semiconductor element with the second portion.

Embodiments will now be described with reference to the figures. The figures are schematic, and the relation between the thickness and the area of a plane of a layer and the ratio of thicknesses of layers may differ from those in actuality. The figures may include components which differ in relations and/or ratios of dimensions in different figures.

Embodiments will be described using a three-dimensional orthogonal coordinate system. A direction of an x axis is referred to as an X direction. A direction opposite to the X direction is referred to as a −X direction. A direction of a y axis is referred to as a Y direction. A direction opposite to the Y direction is referred to as a −Y direction. A direction of a z axis is referred to as a Z direction, and up indicates the Z direction. A direction opposite to the Z direction is referred to as a −Z direction, and down indicates the −Z direction. In an X-Z plane view observed in the +Y direction, up indicates the +Z direction, down indicates the −Z direction, right indicates the +X direction, and left indicates the −X direction.

### 1. First Embodiment

### 1.1. Configuration (Structure)

FIG. 1 shows an example of a structure of a conversion device including a semiconductor device according to the first embodiment. For example, a conversion device 100 converts power. As shown in FIG. 1, the conversion device 100 includes a housing including a bottom portion 101, a side portion 102, and a top portion 103. The housing has an internal space. The conversion device 100 also includes a support body 105, a plurality of cooling fins 106, a support body 107, a spring 108, and a plurality of semiconductor modules 110 in the housing. FIG. 1 shows an example of three semiconductor modules 110.

The support body 105 is made of an insulator, and located on the upper surface of the bottom portion 101. On the upper surface of the support body 105, the plurality of cooling fins 106 and the plurality of semiconductor modules 110 are located on the other. That is, one semiconductor module 110 is placed on the upper surface of one cooling fin 106, and another cooling fin is placed on the upper surface of the one semiconductor module 110. Further semiconductor modules 110 and cooling fins 106 are similarly placed. Two semiconductor modules 110 arranged in the +Z direction are electrically connected.

The support body 107 is made of an insulator, and located on the upper surface of the topmost cooling fin 106. The spring 108 is located on the upper surface of the support body 107, and the upper surface of the spring 108 is in contact with the lower surface of the top portion 103.

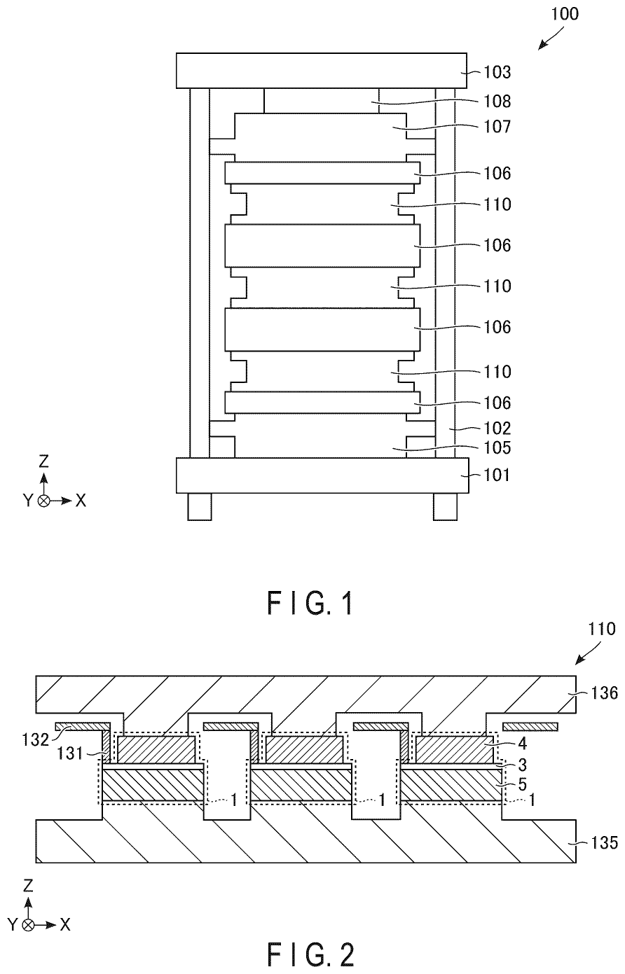

FIG. 2 shows an example of a sectional structure of a semiconductor module including the semiconductor device according to the first embodiment. As shown in FIG. 2, the semiconductor module 110 includes a plurality of semiconductor devices 1, a plurality of conductors 131, a plurality of terminal plates 132, and external electrodes 135 and 136.

The plurality of semiconductor devices 1 are arranged at intervals on the upper surface of the external electrode 135. The semiconductor device 1 includes a semiconductor element 3, an emitter electrode 4, and a collector electrode 5.

The semiconductor element 3 is an element formed in a substrate substantially composed of a semiconductor. In this specification, “substantially” means that a phrase that “substantially” describes does not require literal rigor to the extent of contents that the phrase expresses, but includes an error due to an unavoidable factor.

Examples of the semiconductor element 3 include an IGBT and an IEGT.

The collector electrode 5 is a member made of a conductor such as a metal. The collector electrode 5 is located on the upper surface of the external electrode 135. The semiconductor element 3 is located on the upper surface of the collector electrode 5.

The emitter electrode 4 is a member made of a conductor such as a metal. The emitter electrode 4 is located on the upper surface of the semiconductor element 3.

The conductor 131 is located on the upper surface of the semiconductor element 3, and the lower surface of the conductor 131 is in contact with a gate electrode pad 6 (not shown) of the semiconductor element 3. The lower surface of the terminal plate 132 is in contact with the upper surface of the conductor 131.

The external electrode 135 includes copper (Cu) or is substantially composed of copper. The lower surface of the external electrode 136 is in contact with the upper surfaces of the plurality of semiconductor elements 3. The external electrode 136 includes copper or is substantially composed of copper.

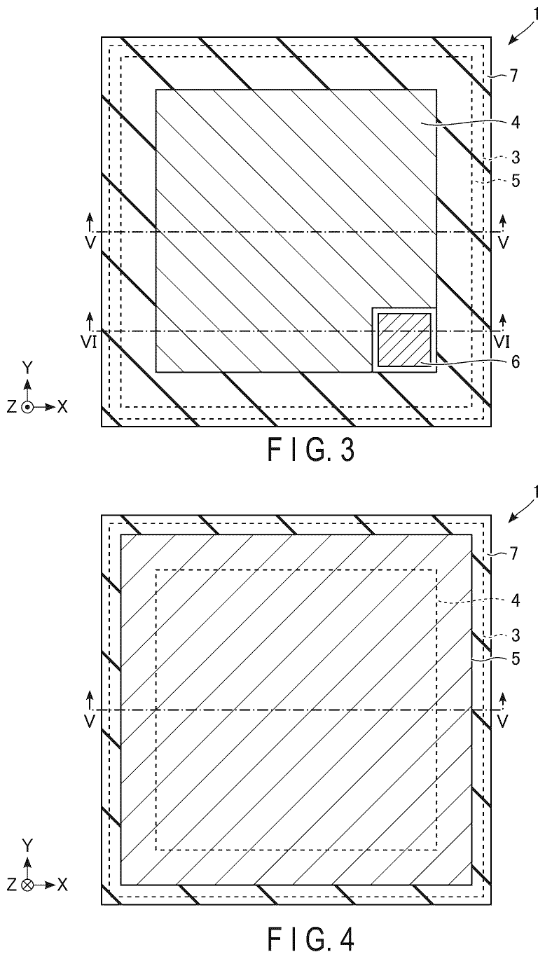

FIGS. 3 and 4 show an example of a planar structure of the semiconductor device according to the first embodiment. FIG. 3 shows the semiconductor device 1 when vied in the −Z direction. FIG. 4 shows the semiconductor device 1 when viewed in the +Z direction.

As shown in FIGS. 3 and 4, the semiconductor device 1 extends along the X-Y plane. The semiconductor element 3 has a quadrilateral shape, and, for example, a rectangular shape, along the X-Y plane. In addition to the semiconductor element 3, the emitter electrode 4, and the collector electrode 5 as described above with reference to FIG. 2, the semiconductor device 1 includes a cover 7. The semiconductor element 3 further includes the gate electrode pad 6.

The emitter electrode 4 has a size that fits inside the edge of the semiconductor element 3 along the X-Y plane. The emitter electrode 4 has, along the X-Y plane, a quadrilateral shape with a corner notched in a quadrilateral shape. For example, the emitter electrode 4 has, along the X-Y plane, a rectangular shape with a corner notched in a rectangular shape. The emitter electrode 4 is in contact with an emitter electrode pad 31 (not shown) of the semiconductor element 3.

The emitter electrode 4 includes one or more of molybdenum (Mo), ruthenium (Ru), tungsten (W), iron (Fe), copper (Cu), cobalt (Co), nickel (Ni), and palladium (Pd). The emitter electrode 4 molybdenum, copper molybdenum, copper tungsten, or invar as the main material, or is substantially composed of molybdenum, copper molybdenum, copper tungsten, or invar.

As described above with reference to FIG. 1, the semiconductor device 1 can be included in the semiconductor module 110, and the plurality of semiconductor modules 110 can be stacked in the conversion device 100. In such an application, the semiconductor device 1 receives a large load. For the purpose of withstanding this load, molybdenum, copper molybdenum, copper tungsten, or invar is used. Each of molybdenum, copper molybdenum, copper tungsten, and invar has a high hardness.

When molybdenum is used, the surface of the emitter electrode 4 may be coated with one or more of nickel, gold (Au), palladium (Pd), and ruthenium (Ru).

Copper molybdenum is an alloy of copper and molybdenum. Copper tungsten is an alloy of copper and tungsten. Each of copper molybdenum and copper tungsten has a higher heat dissipation property than molybdenum, and has smaller thermal expansion than molybdenum.

Invar has smaller thermal expansion than molybdenum. When invar is used, the emitter electrode 4 includes iron and cobalt, or contains iron and nickel.

The collector electrode 5 has a size that fits inside the edge of the semiconductor element 3 along the X-Y plane. The collector electrode 5 has a quadrilateral shape, and, for example, a rectangular shape, along the X-Y plane. The collector electrode 5 is in contact with a collector electrode pad 32 of the semiconductor element 3. The collector electrode 5 is substantially composed of the same material that can be used as the emitter electrode 4.

The gate electrode pad 6 is a member made of a conductor such as a metal. The gate electrode pad 6 is located in the notch portion of the emitter electrode 4. The gate electrode pad 6 has a quadrilateral shape, and, for example, a rectangular shape, along the X-Y plane. The gate electrode pad 6 is spaced from the emitter electrode 4.

The cover 7 is a member made of an insulator. The cover 7 has an annular shape, and has a quadrilateral outline, and, for example, a rectangular outline, along the X-Y plane. The cover 7 is located around the semiconductor element 3 and continuously extends along the edge of the semiconductor element 3. The cover 7 is substantially composed of an insulating resin. Examples of the resin include polytetrafluoroethylene (PTFE).

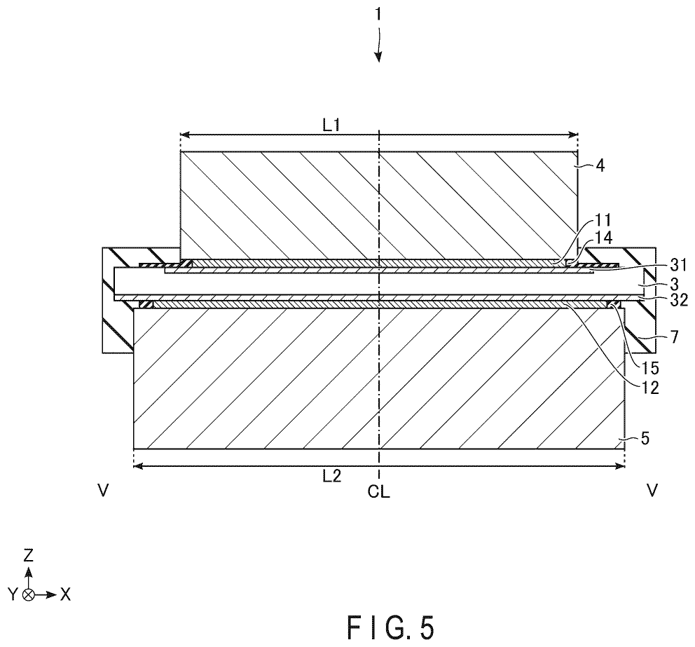

FIG. 5 shows an example of a sectional structure of the semiconductor device according to the first embodiment. FIG. 5 shows the structure along a line V-V in FIGS. 3 and 4, and shows the structure of a section along an X-Z plane. For example, the semiconductor device 1 has the structure shown in FIG. 5 in any X-Z plane and any Y-Z plane not including the gate electrode pad 6.

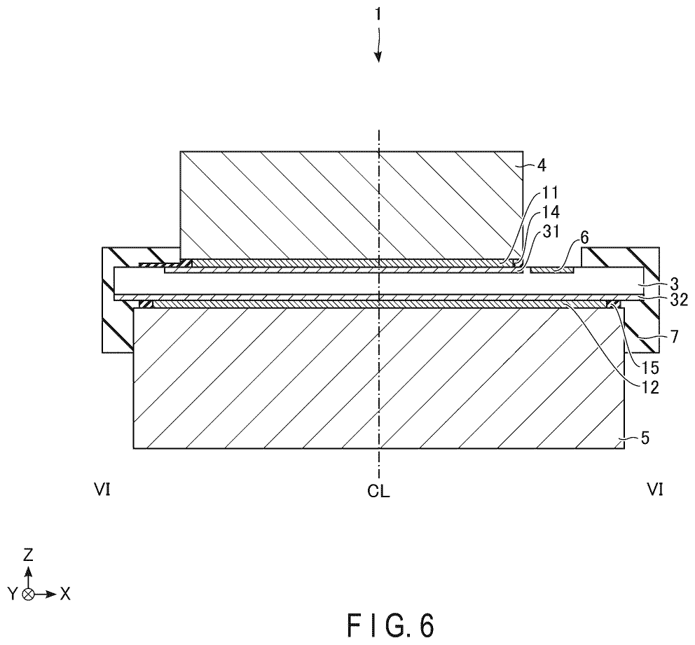

As shown in FIG. 5, the semiconductor device 1 further includes conductors 11 and 12 and insulators 14 and 15. FIG. 5 also shows the emitter electrode pad 31 and the collector electrode pad 32 of the semiconductor element 3. The dimensions and positional relationship of some components shown in FIG. 5 will be described later using FIG. 6.

The emitter electrode pad 31 extends along the X-Y plane, and extends over a region including one of two opposing surfaces of the semiconductor element 3 extending along the X-Y plane. FIG. 5 shows an example in which the emitter electrode pad 31 is located in the upper one of the two opposing surfaces.

The collector electrode pad 32 opposes the emitter electrode pad 31. The collector electrode pad 32 extends along the X-Y plane, and extends over a region including the other of the two opposing surfaces of the semiconductor element 3 extending along the X-Y plane. FIG. 5 shows an example in which the collector electrode pad 32 is located in the lower one of the two opposing surfaces.

The emitter electrode 4 has a cuboid shape with a corner cut out in a cuboid shape. The emitter electrode 4 opposes, via the conductor 11, the surface of the semiconductor element 3 where the emitter electrode pad 31 is located. The emitter electrode 4 has a length L1 in the X direction.

The collector electrode 5 has a cuboid shape, and opposes, via the conductor 12, the surface of the semiconductor element 3 where the collector electrode pad 32 is located. The collector electrode 5 has a length L2 in the X direction. The length L2 is larger than the length L1.

The conductor 11 extends along the X-Y plane. The conductor 11 is located between the emitter electrode pad 31 and the emitter electrode 4, and is in contact with the upper surface of the emitter electrode pad 31 and the lower surface of the emitter electrode 4. The edge of the conductor 11 is located closer to a center line CL of the semiconductor device 1 than the edge of the emitter electrode 4.

Examples of the conductor 11 include a metal, and, for example, a sintered body of a metal. The sintered body is formed by sintering through heating a sheet or paste containing a material for the conductor 11. The conductor 11 is substantially composed of a material that is easily bonded to the emitter electrode 4 based on the material for the emitter electrode 4. The conductor 11 is substantially composed of a metal, and includes one or more of gold, silver (Ag), copper, lead (Pb), tin (Sn), and nickel. The conductor 11 includes gold, silver, copper, or solder as the main material, or is substantially composed of gold, silver, copper, or solder.

Gold is easily bonded to many metals since it is not easily oxidized, and has a higher conductivity and heat dissipation property than solder. Silver can be treated by a generalized technique, is relatively readily available, and has a higher conductivity and heat dissipation property than solder. Copper has a high heat dissipation property, is readily available, and has a higher conductivity and head dissipation property than solder. Solder is readily available, and can be treated by a generalized technique.

The conductor 12 extends along the X-Y plane. The conductor 12 is located between the collector electrode pad 32 and the collector electrode 5, and is in contact with the upper surface of the collector electrode 5 and the lower surface of the collector electrode pad 32. The edge of the conductor 12 is located closer to the center line CL of the semiconductor device 1 than the edge of the collector electrode 5. The conductor 12 is formed by sintering through heating a sheet or paste containing a material for the conductor 12. Examples of the conductor 12 include a metal, for example, a sintered body of a metal. The conductor 12 is substantially composed of a metal, and substantially composed of the same material that can be used as the conductor 11.

The insulator 14 surrounds the conductor 11 along the X-Y plane, is located between the emitter electrode 4 and the upper surface of the semiconductor element 3, and is in contact with the lower surface of the emitter electrode 4 and the upper surface of the semiconductor element 3. Further, the insulator 14 is partially located between the upper surface of the semiconductor element 3 and the cover 7, and covers the region of the upper surface of the semiconductor element 3 other than the region directly under the emitter electrode 4, and the region thereof other than the region above the gate electrode pad 6. The insulator 14 is substantially composed of a heat-resistant organic substance. The insulator 14 includes or is substantially composed of, for example, components contained in the solvent of the paste or sheet containing the elements of the conductor 11. Examples of the components include propylene carbonate.

The insulator 15 surrounds the conductor 12 along the X-Y plane, is located between the collector electrode 5 and the lower surface of the semiconductor element 3, and is in contact with the upper surface of the collector electrode 5 and the lower surface of the semiconductor element 3. The insulator 15 is substantially composed of the same material that can be used as the insulator 14.

The cover 7 covers the region of the upper surface of the semiconductor element 3 other than the region directly under the emitter electrode 4, and the region thereof other than the region above the gate electrode pad 6. The cover 7 also covers the region of the lower surface of the semiconductor element 3 that is not covered with either the insulator 15 or the collector electrode 5. The cover 7 also covers the entire side surface of the semiconductor element 3.

FIG. 6 shows an example of a sectional structure of the semiconductor device according to the first embodiment. FIG. 6 shows the structure along a line VI-VI in FIGS. 3 and 4, and shows the structure of a section along an X-Z plane. For example, the semiconductor device 1 has the structure shown in FIG. 6 in any X-Z plane and any Y-Z plane including the gate electrode pad 6.

As shown in FIG. 6 and described above with reference to FIG. 4, the gate electrode pad 6 is located in the notch portion of the emitter electrode 4. The gate electrode pad 6 is located in a region including the upper surface of the semiconductor element 3. The gate electrode pad 6 is exposed without being covered with the cover 7.

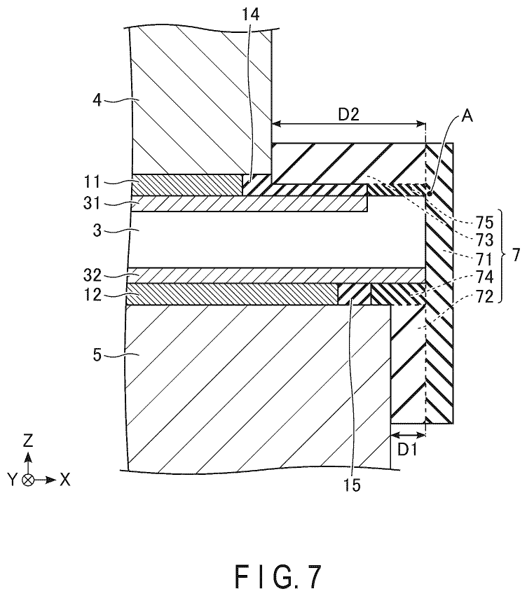

FIG. 7 shows an example of a sectional structure of the semiconductor device according to the first embodiment, and shows a partially enlarged view of the side surface of the semiconductor device 1. As shown in FIG. 7, the edge of the collector electrode 5 and the side surface of the semiconductor element 3 have a distance D1 therebetween. The edge of the emitter electrode 4 and the side surface of the semiconductor element 3 have a distance D2 therebetween. The distance D2 is larger than the distance D1. This is for the following reason. That is, during the operation of the semiconductor element 3 (during voltage application to the emitter electrode 4 and the collector electrode 5), the potential of the collector electrode 5 is transmitted from the corner of the collector electrode 5 to the side surface of the semiconductor element 3, so that the region along and near the side surface of the semiconductor element 3 has the same potential as the collector electrode 5. Accordingly, a point A near the corner formed by the upper surface and side surface of the semiconductor element 3 has the same potential as the collector electrode 5. Hence, if the emitter electrode 4 is close to the point A, discharge may occur between the point A and the emitter electrode 4. To avoid this, the emitter electrode 4 is located at a position far from the point A, and therefore the distance D2 is larger than the distance D1.

The cover 7 includes a first portion 71, a second portion 72, a third portion 73, a fourth portion 74, and a fifth portion 75.

The first portion 71 has a quadrilateral shape. The first portion 71 occupies a region including the entire side surface of the cover 7. The first portion 71 covers the entire side surface of the semiconductor element 3. The first portion 71 extends from the upper end to the lower end of the cover 7.

The second portion 72 has a quadrilateral shape. The second portion 72 occupies a region of the cover 7 between the first portion 71 and the collector electrode 5. The second portion 72 is located in the region including a part of the lower end of the cover 7. The left (the side close to the center line CL of the semiconductor device 1) side surface of the second portion 72 is in contact with the side surface of the collector electrode 5. The upper edge of the second portion 72 is aligned with the upper surface of the collector electrode 5. The right (the side far from the center line CL of the semiconductor device 1) edge of the second portion 72 is connected to the left (the side close to the center line CL of the semiconductor device 1) edge of the first portion 71. The length of the second portion 72 in the X direction, that is, the distance D1 is based on the dimension determined so that the second portion 72 covers at most 5% of the lower surface of the semiconductor element 3.

The third portion 73 has a quadrilateral shape. The third portion 73 occupies a region of the cover 7 between the first portion 71 and the emitter electrode 4. The third portion 73 is located in the region including a part of the upper end of the cover 7. The left (the side close to the center line CL of the semiconductor device 1) side surface of the third portion 73 is in contact with the side surface of the emitter electrode 4. The lower edge of the third portion 73 is located farther in the −Z direction than the lower surface of the emitter electrode 4. The right (the side far from the center line CL of the semiconductor device 1) edge of the third portion 73 is connected to the left (the side close to the center line CL of the semiconductor device 1) edge of the first portion 71. The length of the third portion 73 in the X direction, that is, the distance D2 is based on the dimension determined so that the third portion 73 covers at most 20% of the upper surface of the semiconductor element 3.

The fourth portion 74 occupies a region of the cover 7 between the second portion 72 and the semiconductor element 3 and a region thereof between the collector electrode 5 and the semiconductor element 3. The fourth portion 74 has a quadrilateral shape. The lower edge of the fourth portion 74 is connected to the upper edge of the second portion 72. The right (the side far from the center line CL of the semiconductor device 1) edge of the fourth portion 74 is connected to the left (the side close to the center line CL of the semiconductor device 1) edge of the first portion 71.

The fifth portion 75 occupies a region of the cover 7 between the third portion 73 and the semiconductor element 3. The fifth portion 75 has a quadrilateral shape. The upper edge of the fifth portion 75 is connected to the lower edge of the third portion 73. The right (the side far from the center line CL of the semiconductor device 1) edge of the fifth portion 75 is connected to the left (the side close to the center line CL of the semiconductor device 1) edge of the first portion 71.

The cover 7 covers the portion of the upper surface of the semiconductor element 3 not covered with the emitter electrode 4 and the portion thereof other than the portion above the gate electrode pad 6. The cover 7 covers the portion of the lower surface of the semiconductor element 3 not covered with the collector electrode 5.

The cover 7 sandwiches the upper surface and lower surface of the semiconductor element 3 by the first portion 71, the second portion 72, and the third portion 73. Due to this shape of the cover 7, the cover 7 is fixed to the semiconductor element 3 without using an adhesive.

### 1.2. Manufacturing Method

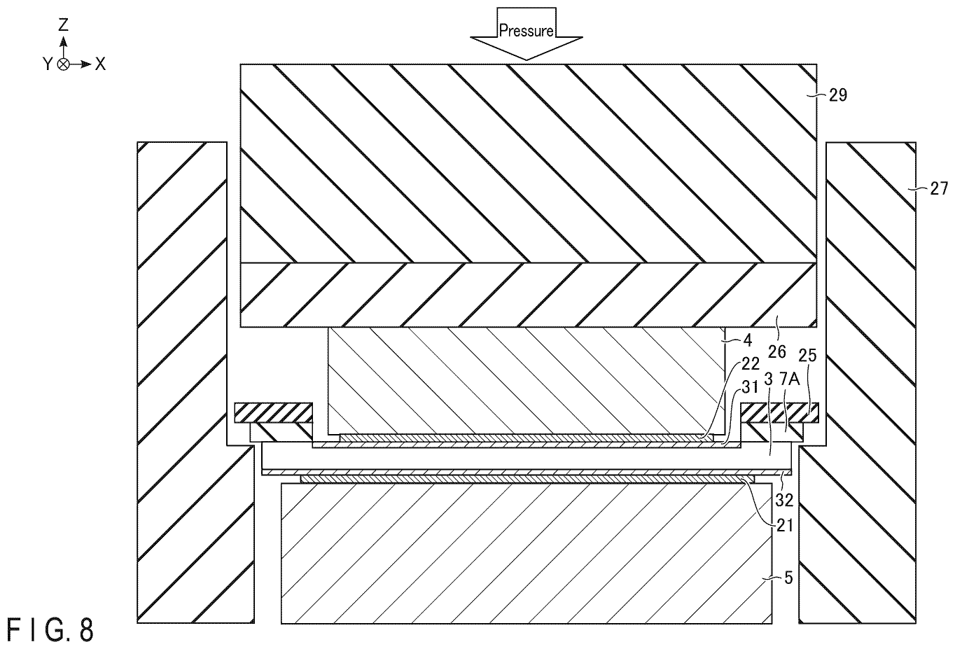

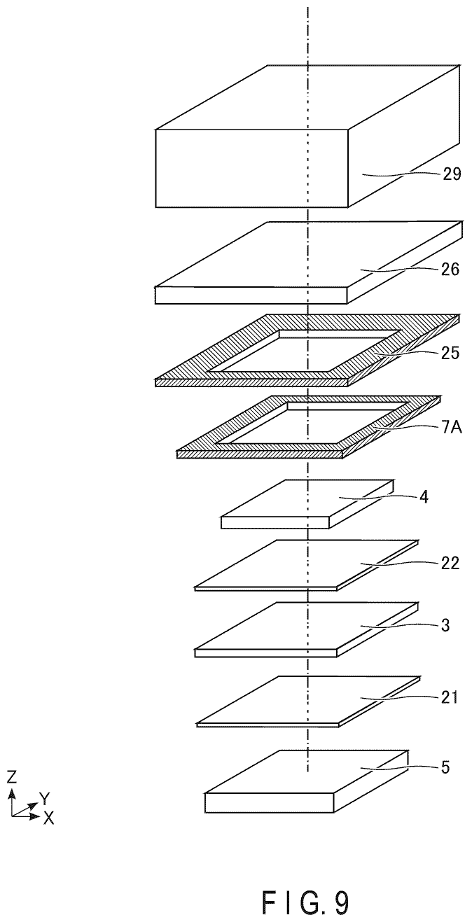

FIGS. 8 and 9 show a part of a manufacturing step of the semiconductor device according to the first embodiment. FIG. 9 shows a state before the collector electrode 5, a bonding material 21, the semiconductor element 3, a boning member 22, the emitter electrode 4, a resin 7A, a jig 25, and a buffer material 26 are stacked.

As shown in FIGS. 8 and 9, in the opening of a mask 27, the collector electrode 5, the bonding material 21, the semiconductor element 3, the bonding material 22, the emitter electrode 4, and the buffer material 26 are stacked in the +Z direction in this order. The cross section of the mask 27 has a rectangular shape with the inside corner notched in a rectangular shape. The lower end of the notch is almost aligned with the upper surface of the semiconductor element 3.

The bonding material 21 includes the conductor 12 together with the insulator 15 as a solvent, and has a sheet or paste shape. The bonding material 22 includes the conductor 11 together with the insulator 14 as a solvent, and has a sheet or paste shape.

The resin 7A is arranged on the upper surface of the semiconductor element 3. The resin 7A is a material that becomes the cover 7 by sintering. The resin 7A has an annular shape, and has an opening larger than the shape of the emitter electrode 4 along the X-Y plane. The resin 7A is arranged on the upper surface of the semiconductor element 3 so as to include the emitter electrode 4 within its opening.

The jig 25 is arranged on the upper surface of the resin 7A. The jig 25 fixes the position of the resin 7A. The jig 25 has an annular shape, and has an opening larger than the shape of the emitter electrode 4 along the X-Y plane. The jig 25 is arranged on the upper surface of the resin 7A so as to include the emitter electrode 4 within its opening.

The buffer material 26 is arranged on the upper surface of the emitter electrode 4. For example, the buffer material 26 is substantially composed of the same material as the cover 7.

In a state in which the collector electrode 5, the bonding material 21, the semiconductor element 3, the bonding material 22, the emitter electrode 4, the resin 7A, the jig 25, and the buffer material 26 are arranged as described above in the opening of the mask 27, the upper surface of the buffer material 26 receives a pressure from a punch 29. While the pressure is applied, the structure constituted by the collector electrode 5, the bonding material 21, the semiconductor element 3, the bonding material 22, the emitter electrode 4, the resin 7A, the jig 25, and the buffer material 26 is heated.

By heating while pressurizing, the bonding material 21 is sintered. As a result, the conductor 12 is formed, and the semiconductor element 3 and the collector electrode 5 are bonded via the conductor 12. In addition, the solvent in the bonding material 21 diffuses, thereby forming the insulator 15.

By heating while pressurizing, the bonding material 22 is sintered. As a result, the conductor 11 is formed, and the semiconductor element 3 and the emitter electrode 4 are bonded via the conductor 11. In addition, the solvent in the bonding material 22 diffuses, thereby forming the insulator 14. Since the area of the emitter electrode 4 along the X-Y plane is smaller than the area of the collector electrode 5 along the X-Y plane, the emitter electrode 4 receives a higher pressure than the collector electrode 5. Accordingly, the solvent in the bonding material 22 spreads more widely than the solvent in the bonding material 21.

By heating while pressurizing, the resin 7A is deformed and spreads. As a result, the resin 7A moves in a region between the mask 27 and the semiconductor element 3, and reaches a region between the semiconductor element 3 and the collector electrode 5. Thus, the cover 7 is formed from the resin 7A. Even if a portion not in contact with the cover 7 is formed in the surface of the semiconductor element 3, the region of this portion between the surface of the semiconductor element 3 and the cover 7 is filled with the solvent in the bonding material 21 or 22, that is, the insulator 15 or 16. Hence, the portion of the surface of the semiconductor element 3 not in contact with the cover 7 is covered with the insulator 14 or 15.

After pressurizing and heating, by performing washing and curing of the cover 7, the semiconductor device 1 is completed.

After curing, the semiconductor device 1 may be heated. This softens the cover 7 and, before softening, the region between the cover 7 and the semiconductor element 3, the emitter electrode 4, or the collector electrode 5 is more reliably filled.

According to the first embodiment the semiconductor device 1 having a high withstand voltage can be provided, as described below.

During the same step as pressurizing and heating described above with reference to FIG. 8, the bonding material and the conductor as its component can protrude from the emitter electrode or the collector electrode in a plane along the X-Y plane. The protruding conductor can cause discharge between the collector electrode and the emitter electrode.

According to the first embodiment, the semiconductor device 1 includes the insulating cover 7 having a shape that covers the side surface of the semiconductor element 3 and sandwiches the upper and lower surfaces of the semiconductor element 3. This suppresses protrusion of the conductor 11 and the conductor 12, so that discharge between the collector electrode 5 and the emitter electrode 4 caused by protrusion of the conductor 11 or 12 is suppressed. Thus, the semiconductor device 1 having a high withstand voltage is realized.

According to the first embodiment, the cover 7 covers the portion of the upper surface of the semiconductor element 3 not covered with the emitter electrode 4, and covers the portion of the lower surface of the semiconductor element 3 not covered with the collector electrode 5. Hence, the cover 7 covers from the end of the collector electrode 5 to the end of the emitter electrode 4. This covering with the cover 7 enhances the insulation of the region between the collector electrode 5 and the emitter electrode 4, and the semiconductor device 1 having a high withstand voltage can be realized.

The semiconductor device 1 includes the insulators 14 and 15. The insulators 14 and 15 partially fill the gap between the cover 7 and the semiconductor element 3, and partially covers the upper surface of the semiconductor element 3. The insulators 14 and 15 are derived from solvents, that is, liquids, and fill the gaps between the cover 7 and the semiconductor element 3 with high precision. Hence, the region between the end of the collector electrode 5 and the end of the emitter electrode 4 is covered with the cover 7 and the insulators 14 and 15 with high precision. This contributes to implementation of the semiconductor device 1 having a high withstand voltage.

The semiconductor device 1 uses no adhesive to fix the cover 7 and the semiconductor element 3. To improve the withstand voltage of a semiconductor element, an insulating chip frame may be attached around the semiconductor element. This attachment can be performed using an adhesive. However, the component of the adhesive, for example, siloxane can degrade the characteristics of the semiconductor element. Since the semiconductor device 1 uses no adhesive to fix the cover 7 and the semiconductor element 3, degradation of the characteristics of the semiconductor element 3 caused by an adhesive is suppressed.

### 1.3. Modification

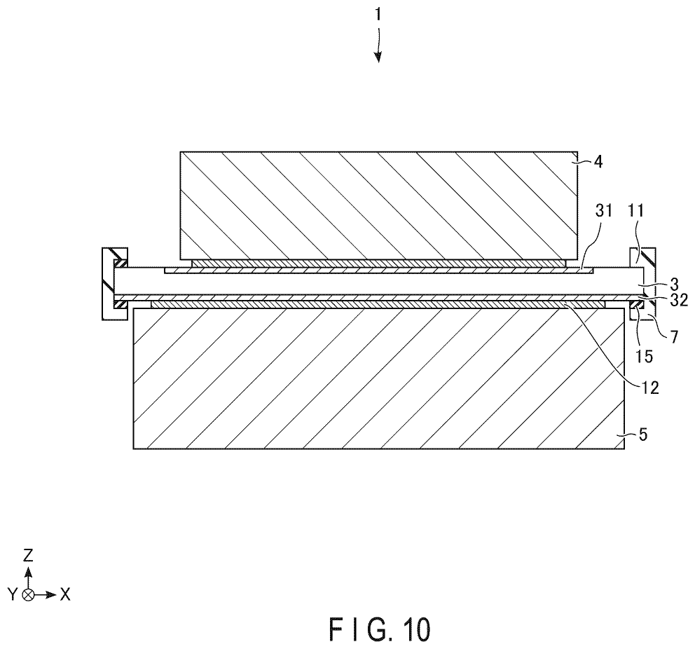

As shown in FIG. 10, the cover 7 may cover the entire side surface of the semiconductor element 3, only the vicinity of the end of the upper surface of the semiconductor element 3, and only the vicinity of the end of the lower surface of the semiconductor element 3. This shape of the cover 7 can be generated when, in the pressurizing and heating step described above with reference to FIG. 8, the pressure and/or temperature are lower than the pressure and/or temperature used in the step shown in FIG. 8. Even the structure shown in FIG. 10 can realize a high withstand voltage since the cover 7 covers the side surface of the semiconductor element 3 which significantly contributes to occurrence of discharge between the collector electrode 5 and the emitter electrode 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor element that
extends along a first plane,
includes a first surface, a second surface opposing the first surface, and a third surface extending between an end of the first surface and an end of the second surface, and
includes a first electrode pad provided in a region including the first surface, and a second electrode pad provided in a region including the second surface;
a first conductor in contact with the first electrode pad;
a first electrode in contact with the first conductor;
a second conductor in contact with the second electrode pad;
a second electrode in contact with the second conductor; and
an insulating cover including a first portion, a second portion, and a third portion, the first portion covering the third surface, the second portion being connected to the first portion and opposing the first surface, and the third portion being connected to the first portion, opposing the second surface, and sandwiching the semiconductor element with the second portion.

2. The semiconductor device according to claim 1, wherein
the cover is continuous across a region facing the first surface, a region facing the second surface, and a region facing the third surface.

3. The semiconductor device according to claim 1 wherein,
the cover continuously surrounds the semiconductor element along the first plane.

4. The semiconductor device according to claim 1, further comprising:
a first insulator on the first surface; and
a second insulator on the second surface,
wherein
the second portion of the cover includes a portion not in contact with the first surface,
the first insulator is located between the first surface and a portion of the second portion of the cover not in contact with the first surface,
the third portion of the cover includes a portion not in contact with the second surface, and
the second insulator is located between the second surface and a portion of the second portion of the cover not in contact with the second surface.

5. The semiconductor device according to claim 1, wherein
the second portion of the cover is in contact with the first electrode, and
the third portion of the cover is in contact with the second electrode.

6. The semiconductor device according to claim 1, wherein
at least one of the first electrode and the second electrode includes one or more of molybdenum, ruthenium, tungsten, iron, copper, cobalt, nickel, and palladium.

7. The semiconductor device according to claim 1, wherein
at least one of the first conductor and the second conductor includes one or more of gold, silver, copper, lead, tin, and nickel.

8. The semiconductor device according to claim 2, wherein
at least one of the first electrode and the second electrode includes one or more of molybdenum, ruthenium, tungsten, iron, copper, cobalt, nickel, and palladium.

9. The semiconductor device according to claim 2, wherein
at least one of the first conductor and the second conductor includes one or more of gold, silver, copper, lead, tin, and nickel.

10. The semiconductor device according to claim 3, wherein
at least one of the first electrode and the second electrode includes one or more of molybdenum, ruthenium, tungsten, iron, copper, cobalt, nickel, and palladium.

11. The semiconductor device according to claim 3, wherein
at least one of the first conductor and the second conductor includes one or more of gold, silver, copper, lead, tin, and nickel.

12. The semiconductor device according to claim 4, wherein
at least one of the first electrode and the second electrode includes one or more of molybdenum, ruthenium, tungsten, iron, copper, cobalt, nickel, and palladium.

13. The semiconductor device according to claim 4, wherein
at least one of the first conductor and the second conductor includes one or more of gold, silver, copper, lead, tin, and nickel.
